(19) United States
(12) Patent Application Publication
(10) Pub. No.: US 2018/0288270 A1
(43) Pub. Date: Oct. 4, 2018

(54) SENSOR UNIT, READING APPARATUS, AND IMAGE FORMING APPARATUS

(71) Applicant: CANON COMPONENTS, INC., Kodama-gun (JP)

(72) Inventors: Toshihiko AMANO, Saitama (JP); Yoshihiro HATTORI, Saitama (JP)

(21) Appl. No.: 15/938,637

(22) Filed: Mar. 28, 2018

(30) Foreign Application Priority Data
Mar. 30, 2017 (JP) 2017-066821
Mar. 23, 2018 (JP) 2018-056593

(51) Int. Cl. H04N 1/193; H01L 25/04; H01L 31/02; H01L 31/0203; H01L 31/0232; H01L 31/147

(52) U.S. Cl. CPC H04N 1/193; H01L 25/042; H01L 31/147; H01L 31/0203; H01L 31/02325; H01L 31/02005

(57) ABSTRACT

An image sensor unit includes multiple elongated-shaped sensor wiring boards provided with sensor chips that generate an electric signal in response to incident light. The sensor wiring boards are arranged such that end faces in the longitudinal direction face each other. A resin material is provided between the end faces of the sensor wiring boards that face each other.

### CROSS-REFERENCE TO RELATED APPLICATIONS

This application is based upon and claims the benefit of priority of the prior Japanese Patent Application No. 2017-066821, filed on Mar. 30, 2017, and the Japanese Patent Application No. 2018-056593, filed on Mar. 23, 2018, the entire contents of which are incorporated herein by reference.

### BACKGROUND OF THE INVENTION

### Field of the Invention

The present invention relates to a sensor unit, a reading apparatus, and an image forming apparatus.

### Description of the Related Art

Reading apparatuses, such as a facsimile or a scanner, and image forming apparatuses, such as a multi-function peripheral of a scanner and a printer, are provided with a sensor unit that reads a reading object. Such a sensor unit includes an elongated-shaped wiring board on which multiple sensor chips are linearly arranged and mounted (hereinafter called a sensor wiring board). A configuration may be adopted where multiple sensor wiring boards mounted with sensor chips are linearly arranged in series to thereby allow the readable dimension of the sensor unit to be larger than the longitudinal direction dimension sensor wiring board.

Multiple light receiving portions (pixels) are arranged in series on the sensor chip. Accordingly, to allow the sensor unit to achieve high-definition reading, it is preferable to perform alignment so that the interval (pixel pitch) between the light receiving portion of the sensor chip mounted on an adjoining one sensor wiring board and the light receiving portion of the sensor chip mounted on the other sensor wiring board at the boundary of the adjoining sensor wiring boards is the same as the interval at other portions.

Patent Document 1 discloses a configuration that makes LED chips protrude from the ends of sensor wiring boards to thereby allow LED chips to be arranged at regular intervals when connecting the adjoining sensor wiring boards to each other. Unfortunately, according to such a configuration, there is a possibility that the protruding portions of the LED chips mounted on the adjoining sensor wiring boards come into contact with each other and are broken when the sensor wiring boards are deformed by an external factor or the like.

### PATENT DOCUMENT 1

Japanese Laid-open Patent Publication No. 07-86541

### SUMMARY OF THE INVENTION

The present invention has been made in view of the problem described above, and is for preventing the sensors provided for the adjoining wiring boards from being broken by sensors coming into contact with each other even when the wiring boards are deformed.

To solve the above problem, a sensor unit according to the present invention includes: a line sensor that includes a plurality of light receiving portions arranged in an aligned manner; and a plurality of elongated-shaped wiring boards provided with the line sensors, wherein a plurality of the wiring boards are arranged such that end faces in a longitudinal direction face each other, at least one of the line sensors protrudes from the end face in a top view of the wiring board, and a resin material is provided between the end faces.

### BRIEF DESCRIPTION OF THE DRAWINGS

FIG. 1 is an external perspective view schematically showing a configuration example of a sensor unit;

FIG. 2 is a sectional view schematically showing the configuration example of the sensor unit;

FIG. 3A is a top view schematically showing an arrangement configuration of a resin material;

FIG. 3B is a side view schematically showing the arrangement configuration of the resin material;

FIG. 4A is a top view schematically showing an arrangement configuration of a resin material;

FIG. 4B is a side view schematically showing the arrangement configuration of the resin material;

FIG. 5A is a top view schematically showing an arrangement configuration of a resin material;

FIG. 5B is a side view schematically showing the arrangement configuration of the resin material;

FIG. 6 is a top view schematically showing a configuration example of a sensor portion to which wiring boards including protrusions are applied;

FIG. 7 is a top view schematically showing a configuration example of a sensor portion to which wiring boards including recesses are applied;

FIG. 8 is an external perspective view schematically showing a configuration example of a multi-function peripheral; and

FIG. 9 is an external perspective view schematically showing a configuration example of an image forming portion of the multi-function peripheral.

### DETAILED DESCRIPTION OF THE PREFERRED EMBODIMENTS

Hereinafter, embodiments to which the present invention is applicable are described in detail with reference to the drawings. According to the embodiments of the present invention, an image sensor unit is shown as an example of a sensor unit. The image sensor unit, and a multi-function peripheral (MFP) to which the image sensor unit is applied are described. The multi-function peripheral is an example of a reading apparatus and an image forming apparatus. In each diagram, the three-dimensional directions of the image sensor unit are indicated by X, Y and Z arrows. The X-direction is the longitudinal direction of the image sensor unit and is, for example, a main-scan direction. The Y-direction is the lateral direction of the image sensor unit and is, for example, a sub-scan direction. The Z-axis direction is the vertical direction of the image sensor unit. In the vertical direction, a sense toward a reading object D is defined as an upward sense, and the opposite sense is defined as a downward sense.

### (Image Sensor Unit)

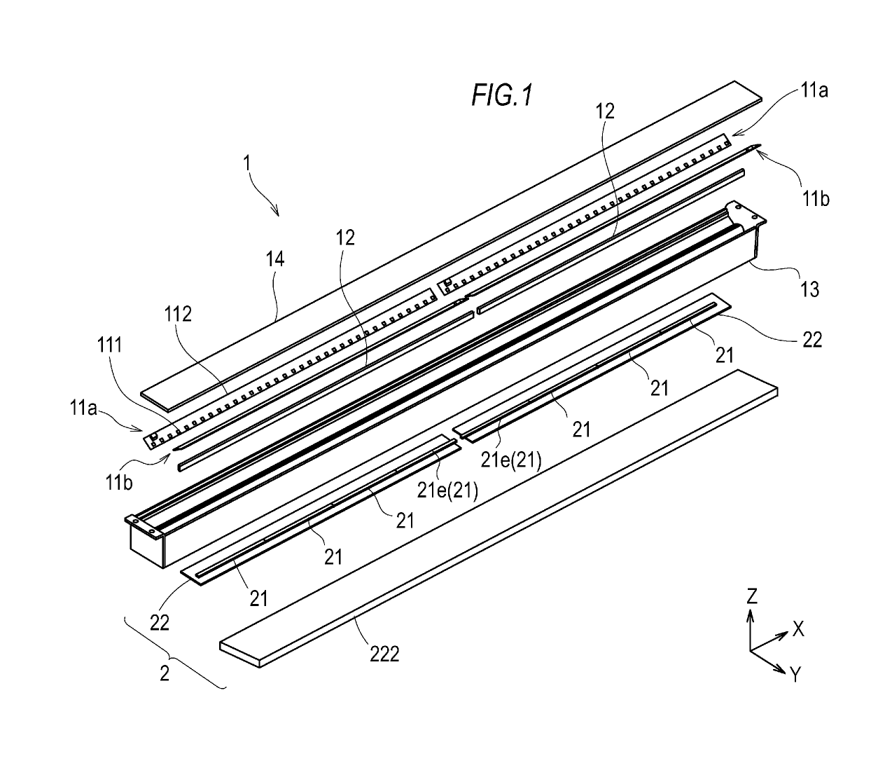

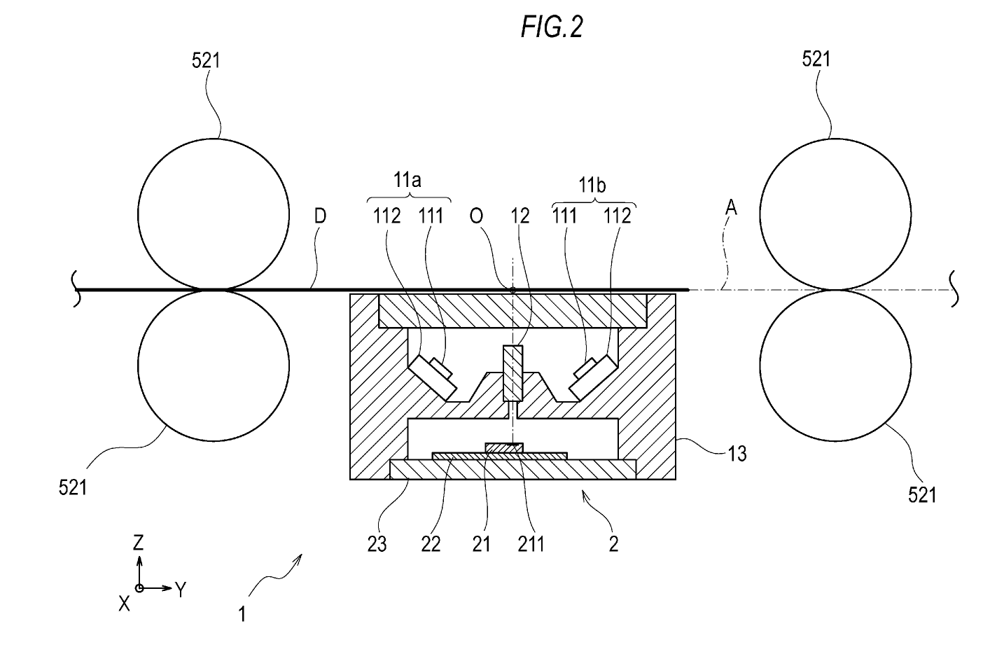

First, a configuration example of the image sensor unit 1, which is an example of the sensor unit, is described with reference to FIGS. 1 and 2. FIG. 1 is an exploded perspective view schematically showing the configuration example of the image sensor unit 1. FIG. 2 is a sectional view schematically showing the configuration example of the image sensor unit 1, and is a sectional view of the image sensor unit 1 taken along a plane perpendicular to the longitudinal direction (main-scan direction). The embodiment of the present invention exemplifies a contact image sensor unit (CIS) as the image sensor unit 1. The image sensor unit 1 according to the embodiment of the present invention supports reading of a large-sized reading object D, such as of A0 size or A1 size.

The image sensor unit 1 includes light sources 11a and 11b, light condensers 12, a sensor portion 2, a housing 13, and a main body cover 14.

The light sources 11a and 11b emit linear light elongated in the longitudinal direction (main-scan direction) of the image sensor unit 1 toward the reading object D. The embodiment of the present invention shows the configuration where the image sensor unit 1 is provided with two pairs of light sources 11a and 11b. Each pair of light sources 11a and 11b includes elongated planar-shaped wiring boards 112, and multiple light emitting elements 111 mounted in a manner linearly arranged in the longitudinal directions of the wiring boards 112. For the sake of description, the wiring boards of the light sources 11a and 11b are called “light source wiring boards 112”. FIG. 1 shows the example where each pair of light sources 11a and 11b includes two light source wiring boards 112. Note that the number of pairs of light sources 11a and 11b provided for the image sensor unit 1 is not limited to two. Alternatively, the number may be one, or three or more. Likewise, the number of light source wiring boards 112 included in each pair of the light sources 11a and 11b is not specifically limited. A configuration where each pair of the light sources 11a and 11b includes one light source wiring board 112 may be adopted. Alternatively, a configuration where each pair includes three or more light source wiring boards 112 may be adopted.

The light source wiring board 112 has a shape elongated in the longitudinal direction (main-scan direction) of the image sensor unit 1. For example, any of publicly known various types of wiring boards, such as ceramic substrates and glass epoxy substrates, is applicable to the light source wiring board 112. In the case of the configuration where each pair of light sources 11a and 11b includes multiple (two or more) light source wiring boards 112, each of the light source wiring boards 112 is arranged linearly (in series) in the longitudinal direction of the image sensor unit 1.

The multiple light emitting elements 111 are mounted on each pair of the light source wiring boards 112 in a manner arranged linearly in the longitudinal direction (main-scan direction). The light emitting elements 111 mounted on the light source wiring board 112 include light emitting elements that emit, for example, red (R), green (G) and blue (B) colors of light. The light emitting elements 111 mounted on the light source wiring boards 117 may further include light emitting elements that emit infrared light, and light emitting elements that emit ultraviolet light. For example, surface mounted LEDs are applicable to these light emitting elements 111.

Each pair of light sources 11a and 11b is only required to have a configuration that can emit linear light elongated in the main-scan direction toward the reading object D. The configuration is not limited to the configuration described above. For example, each pair of light sources 11a and 11b may have a configuration that includes light emitting elements that emit spot-shaped light, and a rod-shaped light guide that linearizes the spot-shaped light which the light emitting elements emit to linear light (achieves a linear light source). The emission colors of the light sources 11a and 11b (the wavelength bands emitted by the light sources 11a and 11b) are not specifically limited. Furthermore, the light emitting elements 111 applied to the light sources 11a and 11b are not limited to the surface mounted LEDs.

The light condenser 12 is an optical member that image-forms light (reflection light and transmission light) from the reading object D on sensor chips 21 described later. For example, a rod lens array is applicable to the light condenser 12. The rod lens array includes multiple erect equal magnification imaging type lens elements (elongated rod lenses) arranged linearly in the longitudinal direction. The multiple imaging elements (rod lenses) are arranged such that the light entering surfaces and/or light emitting surfaces are laterally arranged. The optical axes of the rod lenses are practically in parallel. The light condenser 12 is only required to image-form light from the reading object D on the sensor chips 21 described later. The configuration is not specifically limited. As shown in FIG. 1, the number of light condensers 12 provided for the image sensor unit 1 is not limited. A configuration provided with one light condenser 12 may be adopted. A configuration provided with multiple (two in the example shown in FIG. 1) may be adopted.

The sensor portion 2 includes wiring boards 22 on which a predetermined numbers of sensor chips 21 are mounted, and a base member 23 to which the multiple wiring boards 22 are fixed. For the sake of description, the wiring board 22 of the sensor portion 2 is called “sensor wiring board 22”.

The sensor wiring board 22 has an elongated shape. Any of publicly known various types of wiring boards, such as ceramic substrates and glass epoxy substrates, is applicable to the sensor wiring board 22. The multiple sensor wiring boards 22 are provided so as to be arranged in the longitudinal direction of the image sensor unit 1, with their longitudinal directions being arranged in parallel to the longitudinal direction (main-scan direction) of the image sensor unit 1. End faces 221 of the sensor wiring boards 22 which adjoin to and face each other (i.e., the end faces in the longitudinal direction) are formed to have planes perpendicular to the longitudinal directions of the sensor wiring boards 22.

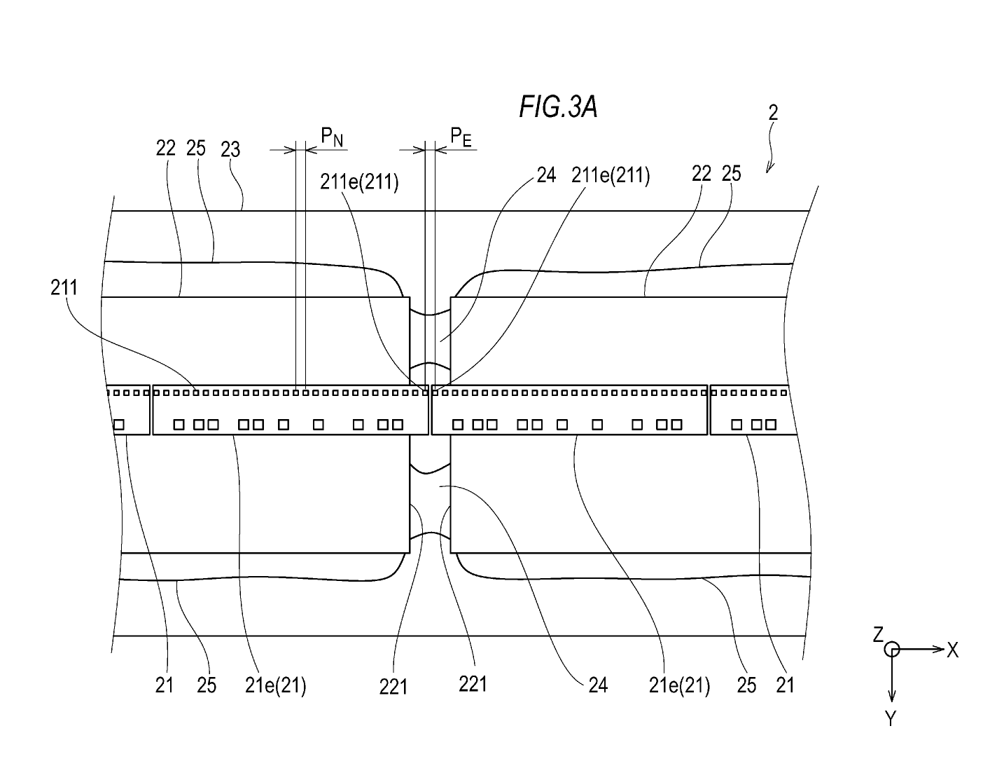

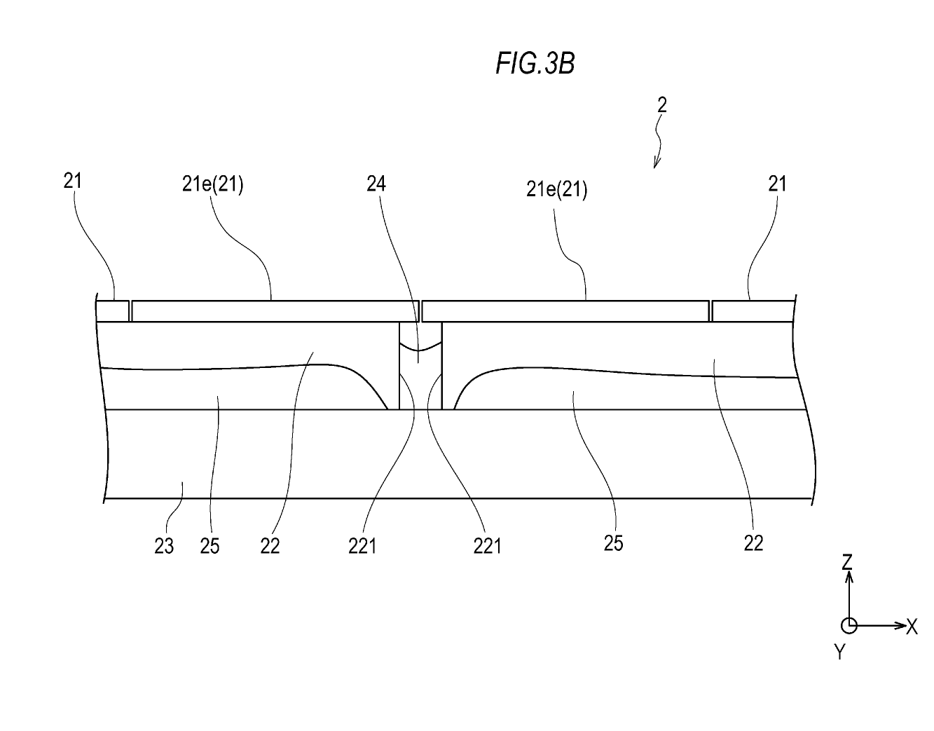

The sensor chips 21 are examples of the line sensors, and are electronic devices (electronic components) that include multiple light receiving portions 211 (photoelectric converter) that are linearly arranged (in an aligned manner) (FIG. 3A). The sensor chip 21 generates an electric signal in response to light having entered the light receiving portion 211, and outputs the signal. In other words, the sensor chip 21 converts the light having entered the light receiving portion 211, into the electric signal. A photodiode array is applicable to the sensor chip 21 (line sensor). The photodiode array is an element (electronic component) that includes multiple photodiodes arranged linearly (aligned manner) at regular intervals. In this case, each of the photodiodes provided for the photodiode array serves as the light receiving portion 211 (photoelectric converter). The predetermined number of sensor chips 21 (line sensors) are mounted such that the light receiving portions 211 of all the sensor chips 21 are arranged linearly in parallel to the longitudinal direction of the sensor wiring board 22. The number of sensor chips 21 (line sensors) mounted on one sensor wiring board 22 is not specifically limited, and is appropriately configured in conformity with the longitudinal direction dimensions of the sensor chips 21 and the sensor wiring board 22.

The base member 23 is a member onto which the multiple sensor wiring boards 22 are fixed. The base member 23 has an elongated shape. The top surface of this member is formed to be a flat surface. The top surface of the base member 23 may be provided with recesses where the multiple sensor wiring boards 22 are fit. In this case, a groove-shaped configuration that extends in the longitudinal direction of the base member 23 is applicable to the recess. The material of the base member 23 is not specifically limited. Ceramic, resin or metal is applicable.

As described above, the sensor portion 2 includes multiple sensor wiring boards 22 on which a predetermined numbers of sensor chips 21 are mounted, and a base member 23 to which the multiple wiring boards 22 are fixed, with the boards being arranged in the longitudinal directions. That is, as described above, the image sensor unit 1 according to the embodiment of the present invention supports reading of the large-sized reading object D, such as of A0 size or A1 size. In the embodiment of the present invention, the sensor wiring boards 22 on which the sensor chips 21 are mounted are arranged linearly in the longitudinal direction (main-scan direction). Accordingly, the reading object D having a larger size than the longitudinal direction dimension of one sensor wiring board 22 can be read. The number of sensor wiring boards 22 provided for the sensor portion 2 are appropriately configured in conformity with the longitudinal direction dimensions of the sensor wiring boards 22 and the size of the corresponding reading object D. That is, it is only required that the total length of the linearly arranged sensor wiring boards 22 is equal to or larger than the width direction dimension of the corresponding reading object D. Alignment between the sensor wiring boards 22, and the structure of fixing the sensor wiring boards 22 to the base member 23 are described later.

The housing 13 is a member that has a function of a casing of the image sensor unit 1. The housing 13 has a configuration having an elongated box shape, for example. A region that can house the light sources 11a and 11b, a region that can house the light condenser 12, and a region that can house the sensor portion 2 are provided in the housing 13. The region that can house the light sources 11a and 11b, and the region that can house the light condenser 12 are provided in the housing 13 in an area closer to the upper side. The region that can house the sensor portion 2 is provided in an area lower than the above area.

The main body cover 14 is a transparent member provided above the housing 13, and has an elongated, rectangular, planar configuration, for example. The main body cover 14 has a function of protecting devices and members housed in the housing 13, and has a function of preventing foreign matters, such as dust, from entering the inside of the housing 13. For example, transparent resin or glass is applicable to the main body cover 14. The configuration of the main body cover 14 is only required to be a configuration that is transparent and can cover the upper side of the housing 13. The specific configuration is not specifically limited. Alternatively, a configuration where the main body cover 14 is not provided for the image sensor unit 1 may be adopted.

Next, the structure of assembling the image sensor unit 1 is described. The light condenser 12 and each pair of light sources 11a and 11b are housed in the housing 13 and are fixed. As shown in FIGS. 1 and 2, the light condenser 12 is housed and fixed in the housing 13 such that the longitudinal direction is parallel to the longitudinal direction (main-scan direction) of the housing 13 and the optical axis is parallel to the vertical direction. For example, ultraviolet cure adhesive or the like is applicable to fixation of the light condenser 12. Each pair of light sources 11a and 11b is housed and fixed in the housing 13 such that the light sources can emit linear light toward a reading line O of the reading object D (the line of intersection between the optical axis of the light condenser 12 and a conveyance path A of the reading object D). For example, each pair of light sources 11a and 11b is provided such that their longitudinal directions are parallel to the longitudinal direction (main-scan direction) of the housing 13 and the optical axes of light emitted therefrom can pass through the reading line 0 of the reading object D in view of the longitudinal direction. FIG. 1 shows the configuration where the image sensor unit 1 includes two pairs of light sources 11a and 11b, and the pairs of light sources 11a and 11b are provided on both the lateral sides of the light condenser 12 (both the sides in the sub-scan direction) in view of the longitudinal direction of the housing 13.

The sensor portion 2 is provided below the light condenser 12. The sensor portion 2 is arranged such that the longitudinal direction of the base member 23 (i.e., the arrangement directions of the sensor wiring boards 22, the arrangement directions of the multiple light receiving portions 211 provided for the sensor chips 21, and the arrangement directions of the sensor chips 21) is parallel to the longitudinal direction (main-scan direction) of the housing 13. The sensor portion 2 is provided such that the light receiving portions 211 of the sensor chips 21 is disposed at the lower focal point of the light condenser 12. The structure of fixing the sensor portion 2 to the housing 13 is not specifically limited. For example, fixation through screwing or with adhesive is applicable.

The main body cover 14 is provided above the housing 13. For example, the main body cover 14 is fixed above the housing 13 with adhesive or two-sided adhesive tape. In a state where the main body cover 14 is fixed to the housing 13, the light condenser 12 and the light sources 11a and 11b housed in the housing 13 are covered with the main body cover 14.

### (Reading Operation of Image Sensor Unit)

Next, an example of the reading operation of the image sensor unit 1 that reads the reading object D is described. Each pair of light sources 11a and 11b of the image sensor unit 1 sequentially emit the colors of light. The light emitted by each pair of light sources 11a and 11b transmits through the main body cover 14, reaches the reading object D (reading line O), is reflected by the surface of the reading object D, transmits through the light condenser 12, and enters the light receiving portions 211 of the sensor chips 12. Every time the light sources 11a and 11b emit each color of light, the sensor chip 21 generates an electric signal in response to the light having entered the light receiving portion 211. Accordingly, one line on the reading object D can be read. The image sensor unit 1 periodically repeats the light emission and the electric signal generation while moving in the sub-scan direction relatively with respect to the reading object D. Accordingly, the image sensor unit 1 can two-dimensionally read the reading object D.

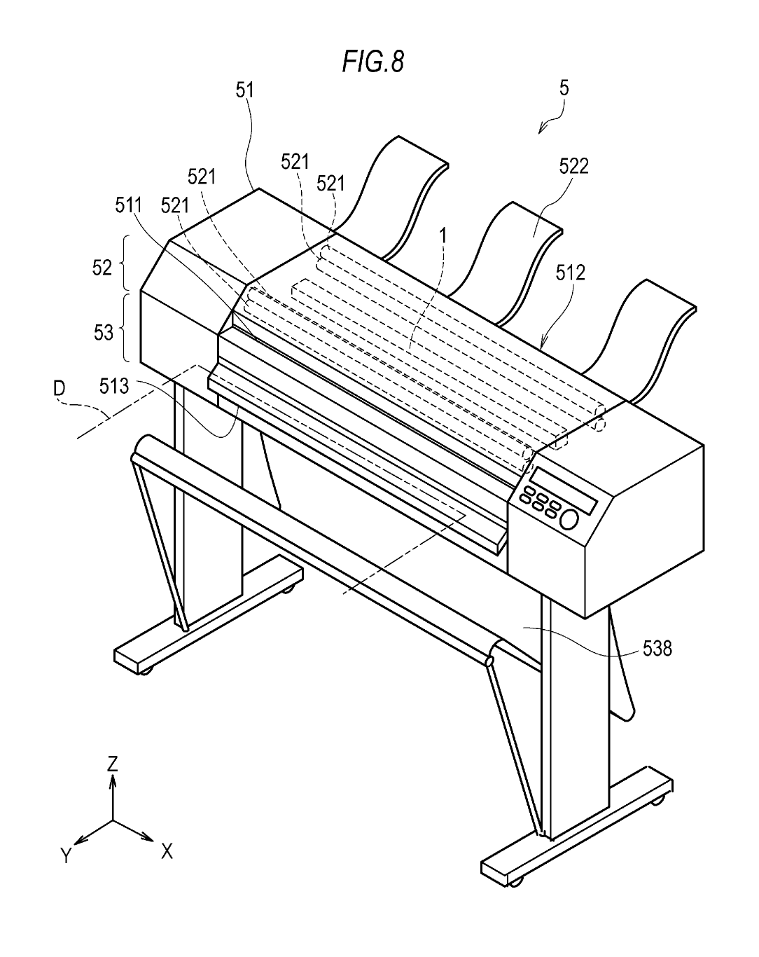

In a case where the image sensor unit 1 is implemented in a multi-function peripheral 5, reading object conveyor rollers 521 (see FIG. 8) provided for the multi-function peripheral 5 convey the reading object D in the sub-scan direction of the image sensor unit 1. Accordingly, the image sensor unit 1 and the reading object D relatively move with respect to each other in the sub-scan direction. A controller of the multi-function peripheral 5 applies drive control to the components (e.g., the light sources 11a and 11b and the sensor chips 21) of the image sensor unit 1, thereby allowing the image sensor unit 1 to read the reading object D.

### (Configuration Example of Sensor Portion)

Next, a configuration example of the sensor portion 2 is described. As shown in FIG. 1, the sensor portion 2 includes multiple sensor wiring boards 22 on which a predetermined numbers of sensor chips 21 are mounted, and a base member 23 to which the multiple wiring boards 22 are fixed. FIG. 1 shows the example where four sensor chips 21 are mounted on each sensor wiring board 22. Alternatively, the number of sensor chips 21 mounted on one sensor wiring board 22 is not specifically limited. FIG. 1 shows the example where the sensor portion 2 includes two sensor wiring boards 22. The number of sensor wiring boards 22 is only required to be two or more (plurality), and is not limited to a specific number. The number of sensor chips 21 and the number of sensor wiring boards 22 are appropriately configured in conformity with the specifications (e.g., a readable size) of the image sensor unit 1 or the like.

FIG. 3A is a top view showing the configuration at a boundary between the sensor wiring boards 22 adjoining to each other in the sensor portion 2, in an enlarged manner. FIG. 3B is a side view of FIG. 3A in view of the sub-scan direction. As shown in FIG. 3A, the sensor chips 21 include linearly arranged light receiving portions 211 (photoelectric converters). As described above, the sensor chips 21 are mounted on the sensor wiring board 22 such that the multiple light receiving portions 211 are linearly arranged in parallel to the longitudinal direction (main-scan direction) of the sensor wiring board 22.

As shown in FIG. 3A, among the sensor chips 21 (line sensors) mounted on each sensor wiring board 22, the sensor chips 21 provided at the outermost ends in the longitudinal direction (hereinafter, sometimes described as “sensor chips 21e at the ends” in an abbreviated manner) adjoin each other at the boundary between the adjoining sensor wiring boards 22. The adjoining sensor wiring boards 22 are aligned to each other such that among the light receiving portions 211 included in the two sensor chips 21e at the ends adjoining each other, the interval P_{E} between the light receiving portions 211e provided at the outermost end in the longitudinal direction and directly adjoining each other is the same as the interval P_{N} of the other light receiving portions 211 the interval between light receiving portions 211 on the sensor chips 21e at the ends). In the configuration where the sensor portion 2 includes three or more sensor wiring boards 22, all the sensor wiring boards 22 are aligned to each other as described above. According to such a configuration, the intervals of the light receiving portions 211 are equal to each other over the entire length of the sensor portion 2. Consequently, improvement in the reading image quality can be facilitated. The interval P_{E} between the adjoining light receiving portions 211e is not necessarily the same as the interval P_{N} between the other light receiving portions 211. In this case, it is preferable that the interval P_{E} between the adjoining light receiving portions 211e be between 50 and 300% of the interval P_{N} between the other light receiving portions 211 (the light receiving portions 211 other than the light receiving portions 211e at the ends), and it is more preferable that the interval P_{E} be between 80 and 250%. The interval P_{N} between the light receiving portions 211 other than the light receiving portions 211e at the ends is smaller than the interval between the end faces 221 of the adjoining sensor wiring boards 22 (see FIG. 3A).

As shown in FIGS. 3A and 3B, a part of the sensor chips 21e at the end in the longitudinal direction protrudes from the end face 221 in the longitudinal direction of the sensor wiring board 22 in the longitudinal direction of the sensor wiring board 22. That is, at least one of the sensor chips 21 (line sensors) mounted on the wiring board 22 protrudes from the end face. Such a configuration prevents the adjoining sensor wiring boards 22 from interfering with each other, and can achieve the alignment as described above. That is, if the configuration where the sensor chips 21e at the ends do not protrude from the end faces 221 of the sensor wiring boards 22 is adopted, the sensor chips 21e at the ends cannot be closer to each other than at the positions where the end faces 221 of the adjoining sensor wiring boards 22 are in contact with each other. Consequently, in this case, the interval P_{E} between the light receiving portions 211e of the sensor chips 21e at the ends that directly adjoin each other and the interval P_{N} between the other light receiving portions 211 cannot have a desired relationship. On the contrary, if the configuration where the parts of the sensor chips 21e at the ends in the longitudinal direction protrude from the end faces 221 in the longitudinal direction of the sensor wiring boards 22 is adopted, the sensor chips 21e at the ends can be disposed close to each other without interference due to the sensor wiring boards 22. Consequently, alignment can be achieved so that the interval P_{E} between the light receiving portions 211e of the sensor chips 21e at the ends that directly adjoin each other and the interval P_{N} between the other light receiving portions 211 can have the relationship described above.

As shown in FIGS. 3A and 3B, a material 24 that is a resin material or includes a resin material is provided between the adjoining sensor wiring boards (more specifically, between the end faces 221 that are in the longitudinal direction and are of the sensor wiring boards 22 that face each other). The sensor wiring boards 22 are held (fixed) in a state of being aligned with each other by the material 24 that is the resin material or includes the resin material. In other words, the distance between the adjoining sensor wiring boards 22 is held (fixed) by the material 24 that is the resin material or includes the resin material. The material 24 that is the resin material or includes the resin material is provided so as to be in contact with both the sensor wiring boards 22 that adjoin with each other (in particular, the end faces 221 in the longitudinal direction). In other words, the material 24 that is the resin material or includes the resin material is provided across the adjoining sensor wiring boards 22 (across the end faces 221). Furthermore, the material 24 that is the resin material or includes the resin material is in contact with the base member 23 at least between the sensor wiring boards 22 that adjoin each other. The material 24 that is the resin material or includes the resin material is only required to be disposed between the sensor wiring boards 22 that adjoin each other, and is not necessarily provided in contact with both the sensor wiring boards 22. For example, the material 24 that is the resin material or includes the resin material may be provided in contact with one of the sensor wiring boards 22, or provided with contact with none of the sensor wiring boards 22. Contact between the sensor wiring boards 22 can prevent the sensor chips 21e from coming into contact. Furthermore, the sensor chips 21e can be prevented from being broken owing thereto.

As described above, the sensor chips 21e at the ends protrude from the end faces 221 in the longitudinal direction of the sensor wiring boards 22 in the longitudinal direction. Accordingly, in the case where the adjoining sensor wiring boards 22 are aligned with each other as described above, a gap is formed between the end faces 221 of the adjoining sensor wiring boards 22. The material 24 that is the resin material or includes the resin material is provided in the gap.

The material 24 that is the resin material or includes the resin material applied to the embodiment of the present invention may be a solid substance that has fluidity before curing (before polymerization) and does not have the fluidity after curing (after polymerization) (a solid substance having a predetermined hardness so as to hold certain dimensions and shape). Such a material 24 that is the resin material or includes the resin material may be any of various types of adhesives made of polymer materials, and various types of adhesives containing a polymer material, such as an adhesive made of a photo-curable resin material (photo-curable types include an ultraviolet cure type), an adhesive containing a photo-curable resin material, a cyanoacrylate resin adhesive, for example. The adhesive made of the photo-curable resin material, and the adhesive that contains the photo-curable resin material may be, for example, an acrylic adhesive (an adhesive containing urethane acrylate) and epoxy adhesive (an adhesive containing epoxy acrylate).

According to the configuration where the material 24 that is the resin material or includes the resin material is provided between the adjoining sensor wiring boards 22, the adjoining sensor wiring boards 22 are prevented from being close to or in contact with each other even if the sensor wiring boards 22 are deformed. That is, even if the sensor wiring boards 22 are deformed, the material 24 that is the resin material or includes the resin material provided between the adjoining sensor wiring boards 22 in an intervening manner holds the distance. Accordingly, the sensor chips 21e at the ends provided on the close sides of the adjoining sensor wiring boards 22 are prevented from coming into contact, and the sensor chips 21e at the ends are prevented from being broken.

The sensor wiring boards 22 may have a configuration of adhering to the base member 23 with an adhesive member 25 other than the material 24 that is the resin material or includes the resin material between the adjoining sensor wiring boards 22. In this case, the material of the adhesive member 25 is not specifically limited. For example, in a manner analogous to that of the material 24 that is the resin material or includes the resin material between the adjoining sensor wiring boards 22, any of various types of adhesives made of polymer materials, and various types of adhesives containing a polymer material, such as an adhesive made of a photo-curable resin material (photo-curable types include an ultraviolet cure type), an adhesive containing a photo-curable resin material, a cyanoacrylate resin adhesive is applicable. The other adhesive member 25 may be made of a material different from that of the material 24 that is the resin material or includes the resin material between the adjoining sensor wiring boards 22. Furthermore, the position and range where the other adhesive member 25 is provided are not specifically limited. Accordingly, only if the configuration of using the other adhesive member 25 is adopted, the sensor wiring boards 22 adhere and are fixed strongly to the base member 23.

### (Alignment Method)

Next, a method of aligning the sensor wiring boards 22 is described. It is assumed that a predetermined number of sensor chips 21 are preliminarily embedded on the sensor wiring board 22. An operator aligns the multiple sensor wiring boards 22 mounted on the top surface of the base member 23 (but not fixed to the base member 23) as described above. For example, while the positions of the light receiving portions 211 of the sensor chips 21e at the ends are confirmed using a microscope or the like, the adjoining sensor wiring boards 22 are aligned such that the interval P_{E} between the light receiving portions 211e of the sensor chips 21e at the ends that adjoin each other, and the interval P_{N} between the other light receiving portions 211 can have the relationship described above.

After completion of the alignment, a polymer material or a material containing a polymer material (material 24 that is the resin material before curing (before polymerization) or includes the resin material) is provided between the adjoining sensor wiring boards 22. The material 24 that is the resin material or includes the resin material is the polymer material before curing (before polymerization) or a material containing the polymer material, and has the fluidity. A gap is formed between the end faces 221 of the adjoining sensor wiring boards 22. Accordingly, the operator or the like pours or drops the polymer material having the fluidity or the material containing the polymer material into the gap, thereby providing the material so as to come into contact with both the adjoining sensor wiring boards 22 and the base member 23.

Subsequently, the polymer material before polymerization or the material containing the polymer material is polymerized and thus cured. The curing method is appropriately selected in conformity with the type of the polymer material. For example, in the case of the photo-curable polymer material, the material is irradiated with light having a predetermined wavelength and thus polymerized. The polymer material or the material containing the polymer material is cured after completion of the polymerization. Accordingly, after completion of the polymerization, the adjoining sensor wiring boards 22 is held in a state of being aligned by the material 24 that is the resin material or includes the resin material (the cured polymer material or the material containing the polymer material), and is thus fixed to the base member 23.

As described above, in a case of the configuration of using the material 24 which is the resin material obtained by curing the polymer material or the material containing the polymer material or which includes the resin material, the adjoining sensor wiring boards 22 can be fixed in the state of being aligned, and the sensor wiring boards 22 can be fixed to the base member 23. Consequently, the operation of holding (fixing) the sensor wiring boards 22 in the aligned state is facilitated. According to use of the polymer material that has the fluidity or the material containing the polymer material, the sensor wiring boards 22 are aligned with each other, and subsequently, the material 24 that is the resin material or includes the resin material and has any dimension can be provided between the sensor wiring boards 22. Consequently, for example, in comparison with the configuration where the rigid member (the solid member that holds the predetermined dimensions and shape) is disposed between the wirings, improvement in alignment and improvement in flexibility can be facilitated.

Here, an example of arrangement of the materials 24 that are each the resin material or include the resin material and are used for aligning the sensor wiring boards 22 is described.

FIGS. 3A and 3B shows an example of the configuration where the materials 24 that are each the resin material or include the resin material are provided at two sites in the gap between the end faces 221 of the adjoining sensor wiring boards 22. Preferably, the configuration is adopted where the materials 24 that are each the resin material or include the resin material at the two sites are provided at positions without overlapping with the sensor chips 21e at the ends in the top view (not seen to overlap). In particular, preferably, a configuration is adopted where the materials 24 that are each the resin material or include the resin material at the two sites are provided on both the sides of the sensor chips 21e at the ends in the sub-scan direction. Such a configuration facilitates the operation of providing the polymer material before curing (polymerization) or the material containing the polymer material. The polymer material before curing or the material containing the polymer material is prevented from adhering to the sensor chips 21e at the ends. Furthermore, according to a configuration provided on both the sides of the sensor chips 21e at the ends, the arrangement direction of the light receiving portions 211 is maintained in parallel to the main-scan direction even if the dimensions of the materials 24 that are each the resin material or include the resin material, the sensor wiring board 22 or the base member 23 are changed.

FIG. 3A exemplifies the configuration where materials 24 that are each the resin material or include the resin material are provided at two sites. However, the number of sites where the materials 24 that are each the resin material or include the resin material are provided is not limited to two. For example, configurations provided at two or more sites, such as three or four sites, may be adopted. Even with the configuration where the materials 24 that are each the resin material or include the resin material are provided at two or more sites, it is preferable that the configuration should be adopted where the materials 24 that are each the resin material or include the resin material at the two sites are provided at positions without overlapping with the sensor chips 21e at the ends in the top view (not seen to overlap).

In the example shown in FIGS. 3A and 3B, the height (the position of the top surface in the vertical direction) of the material 24 that is the resin material or includes the resin material is not specifically limited. The height of the material 24 that is the resin material or includes the resin material may be lower than that of the sensor chips 21e at the ends (lower than the top surfaces of the sensor wiring boards 22), substantially identical to that of the sensor chips 21e at the ends as shown in FIG. 3B, or higher than the top surfaces of the sensor chips 21e at the ends. As described above, if the configuration is adopted where the materials 24 that are each the resin material or include the resin material at the two sites are provided at positions without overlapping with the sensor chips 21e at the ends (not seen to overlap) in the top view, the materials do not come into contact with the sensor chips 21 even though the heights are higher than the sensor chips 21e at the ends.

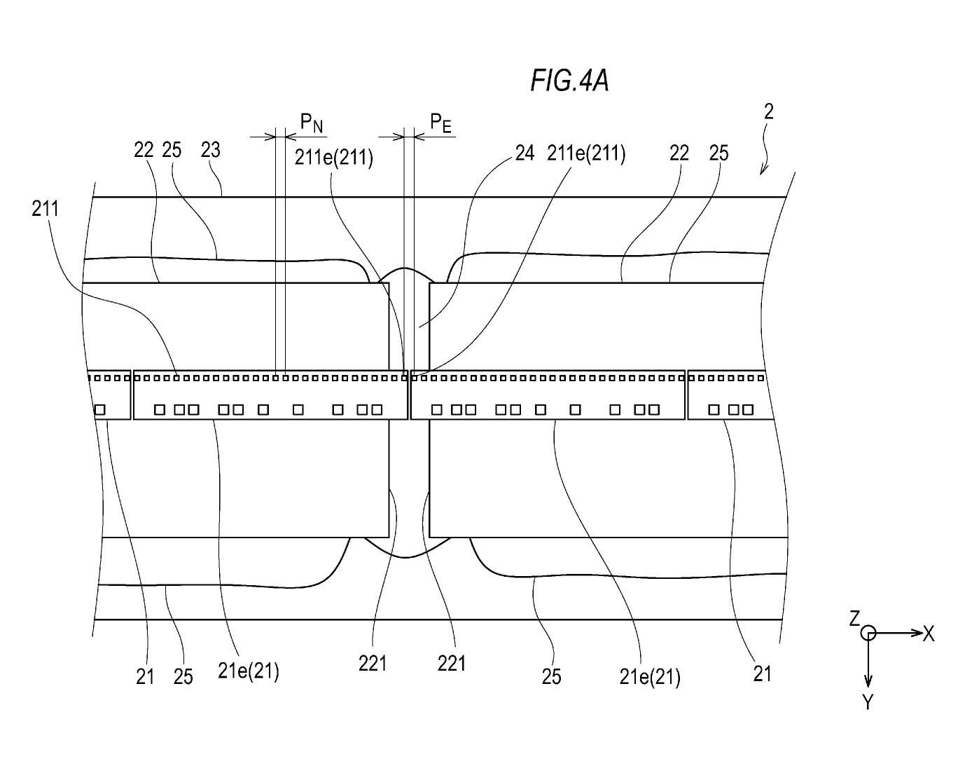

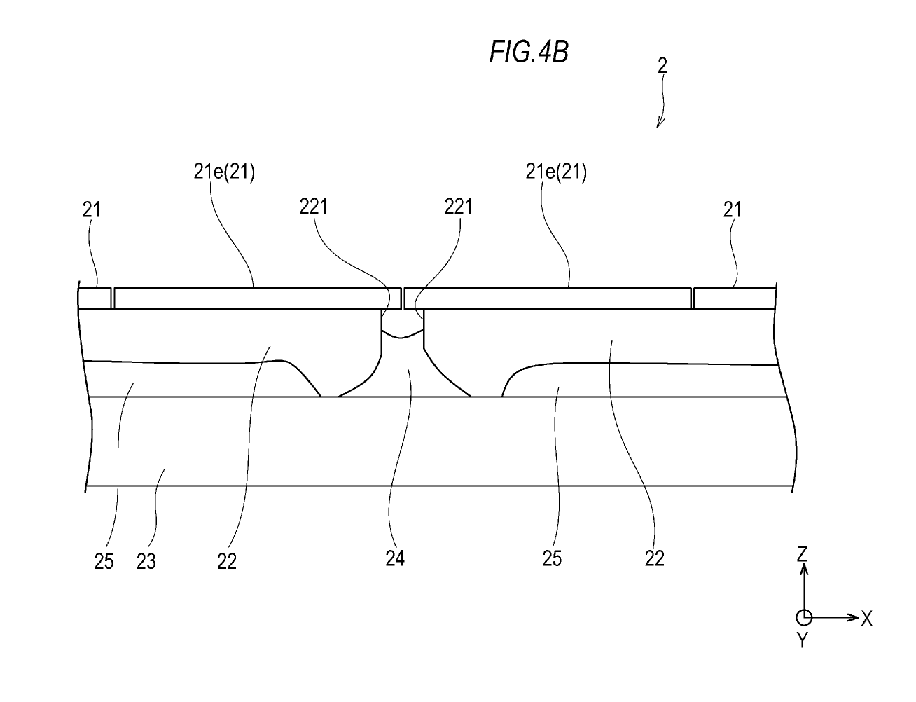

FIGS. 4A and 4B show an example of the configuration where the materials 24 that are each the resin material or include the resin material are provided over the entire region (i.e., over the entire length in lateral direction) in gap between the end faces 221 of the adjoining sensor wiring boards 22. In this way, the configuration where the materials 24 that are each the resin material or include the resin material are provided over the entire region in the gap between the end faces 221 of the adjoining sensor wiring boards 22 may be adopted. According to such a configuration, the adjoining sensor wiring boards 22 are caused to strongly adhere to each other with the material 24 that is the resin material or includes the resin material, and the aligned state is strongly held. In this case, preferably, the height of the material 24 that is the resin material or includes the resin material is equal to or lower than the height of the sensor chips 21e at the ends as shown in FIG. 4B.

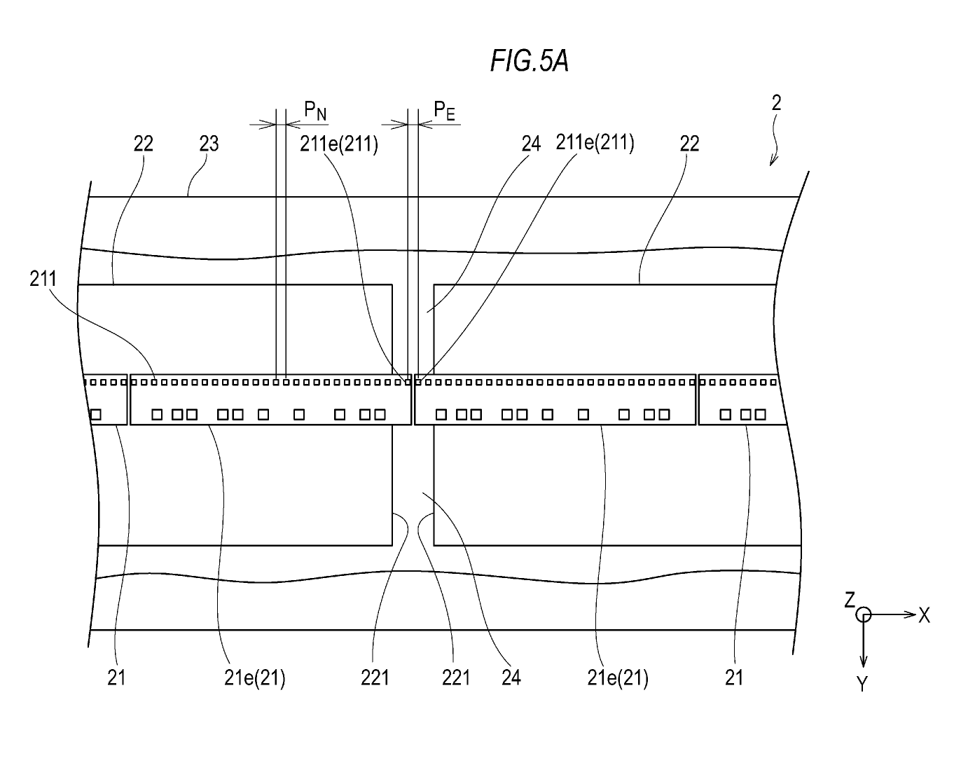

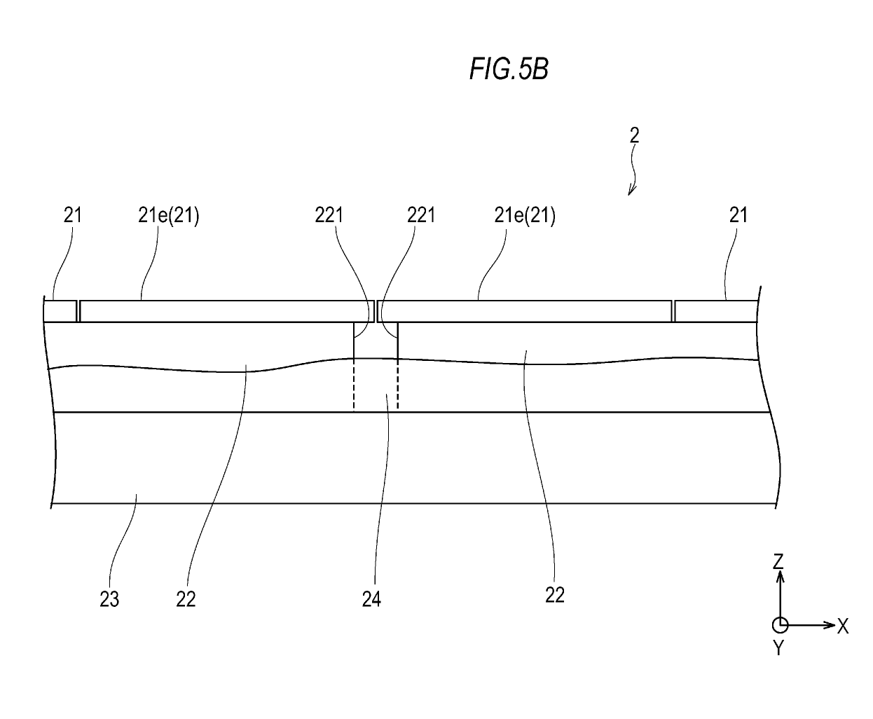

FIGS. 5A and 5B show an example of a configuration where the material 24 that is the resin material or includes the resin material is provided not only in the gap between the adjoining sensor wiring boards 22 but also along the long sides of the sensor wiring boards 22. According to such a configuration, the sensor wiring boards 22 strongly adhere to the base member 23. In this case, a configuration may be adopted where the material 24 that is the resin material or includes the resin material is provided over the entire lengths of the long sides of the sensor wiring boards 22 in the top view without any gap (without any cut). Alternatively, a configuration where the material 24 is partially provided may be adopted. In this case, another adhesive member 25 is not necessarily provided. A configuration may be adopted where the other adhesive member 25 is configured integrally with an adhesive member 25 other than the material 24 that is the resin material or includes the resin material between the adjoining sensor wiring boards 22.

Any of the configurations in FIGS. 3A to 5B can exert the advantageous effects described above. That is, even when the sensor wiring boards 22 are deformed by an external factor or the like, the material 24 that is the resin material or includes the resin material provided between the adjoining sensor wiring boards 22 prevents the adjoining sensor wiring boards 22 from getting close to or coming into contact with each other. Consequently, the sensor chips 21e at the ends are prevented from coming into contact with each other, and the sensor chips 21e at the ends are prevented from being broken.

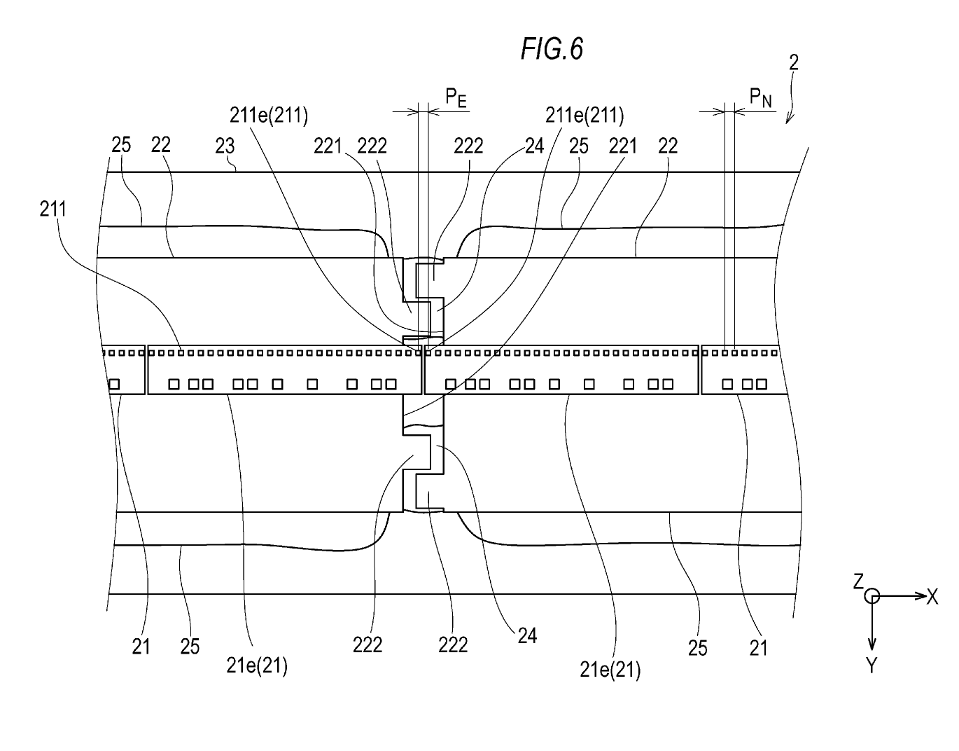

Protrusions 222 may be provided for the end faces 221 of the sensor wiring board 22 in the longitudinal direction. FIG. 6 is a top view showing an example where the sensor wiring boards 22 provided with the protrusions 222 at the end faces 221 in the longitudinal direction are applied. As described above, parts of the sensor chips 21e at the ends protrude from the end faces 221 in the longitudal direction of the sensor wiring boards 22. Consequently, there is a possibility that the sensor chips 21e at the ends come into contact with another member, object or the like and are broken at a stage before the sensor wiring boards 22 adheres to the base member 23.

Accordingly, as shown in FIG. 6, the protrusions 222 are provided at the end faces 221 of the sensor wiring boards 22, thereby reducing the possibility that the sensor chips 21e at the ends come into contact with another member, object or the like and are broken. More specifically, as shown in FIG. 6, two protrusions 222 that protrude in the longitudinal direction in the top view are provided on the end faces 221 of the sensor wiring boards 22. The dimensions of protrusions of the two protrusions 222 from the end faces 221 are larger than the dimensions of protrusion of the sensor chips 21e at the ends from the end faces 221 of the sensor chips 21e at the ends. In the top view, the two protrusions 222 are provided on each of both the sides of the sensor chips 21 in the lateral direction. In the other words, the portions protruding from the end faces 221 of the sensor chips 21e at the ends are disposed between the two protrusions 222.

Such a configuration can prevent the sensor chips 21e at the ends from being broken owing to contact therebetween. Furthermore, contact of the protrusions 222 with another member, object or the like can reduce the possibility that the sensor chips 21e at the ends contact with another member, object or the like and are broken. That is, these protrusions 222 protect the sensor chips 21e at the ends. As shown in FIG. 6, to prevent the protrusions 222 from being interfered with each other during alignment of the adjoining sensor wiring boards 22, the protrusions 222 provided on the end faces 221 opposite to each other are provided at positions that deviate in the lateral direction.

Alternatively, a configuration may be adopted where recesses 223 are provided at positions where the end faces 221 of the sensor wiring boards 22 in the longitudinal direction. According to such a configuration, the position where the materials 24 that are each the resin material or include the resin material are provided become clear. That is, it becomes clear that a region between the recesses 223 on the end faces 221 of the sensor wiring boards 22 in the longitudinal direction (in other words, a region encircled by the two recesses 223 opposite in the top view) is a position where the material 24 that is the resin material or includes the resin material is provided. Such a configuration can facilitate arrangement (reception) of the polymer material before curing or the material containing the polymer material between the recesses 223. The polymer material or the material containing the polymer material provided between the recesses 223 are prevented from flowing out between the recesses 223. Consequently, the polymer material or the material containing the polymer material is prevented from flowing to an unnecessary position.

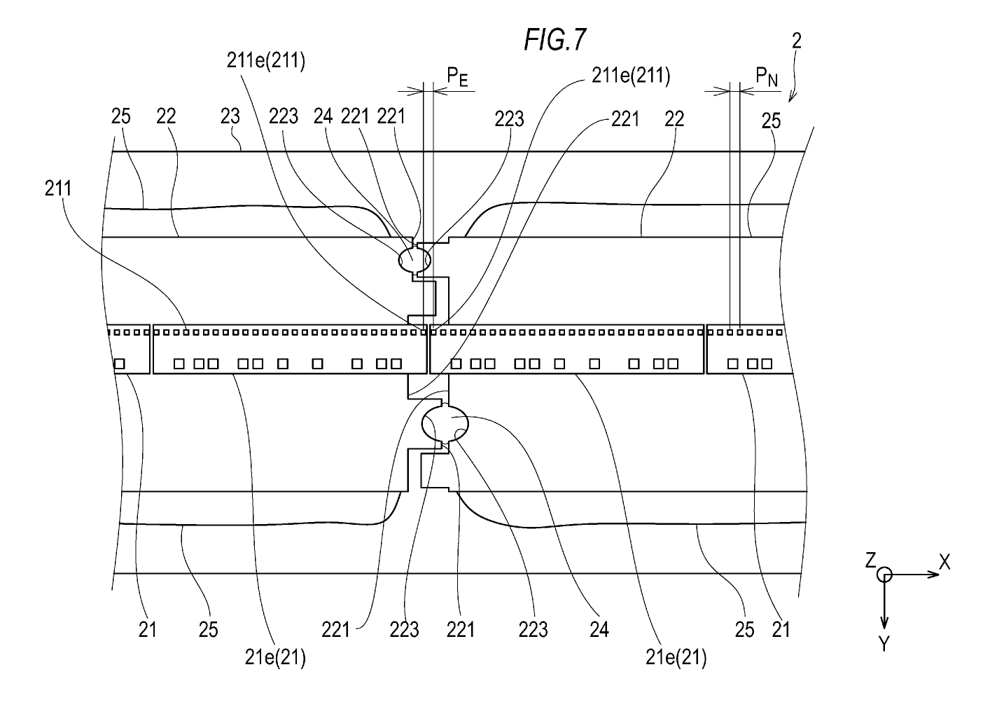

The specific shapes, dimensions and positions of the recesses 223 are not specifically limited. FIG. 7 shows a configuration where the recesses 223 are provided for both the adjoining two sensor wiring boards 22. Alternatively, a configuration provided for only one sensor wiring board 22 may be adopted. (Configuration example of a multi-function peripheral (reading apparatus, image forming apparatus))

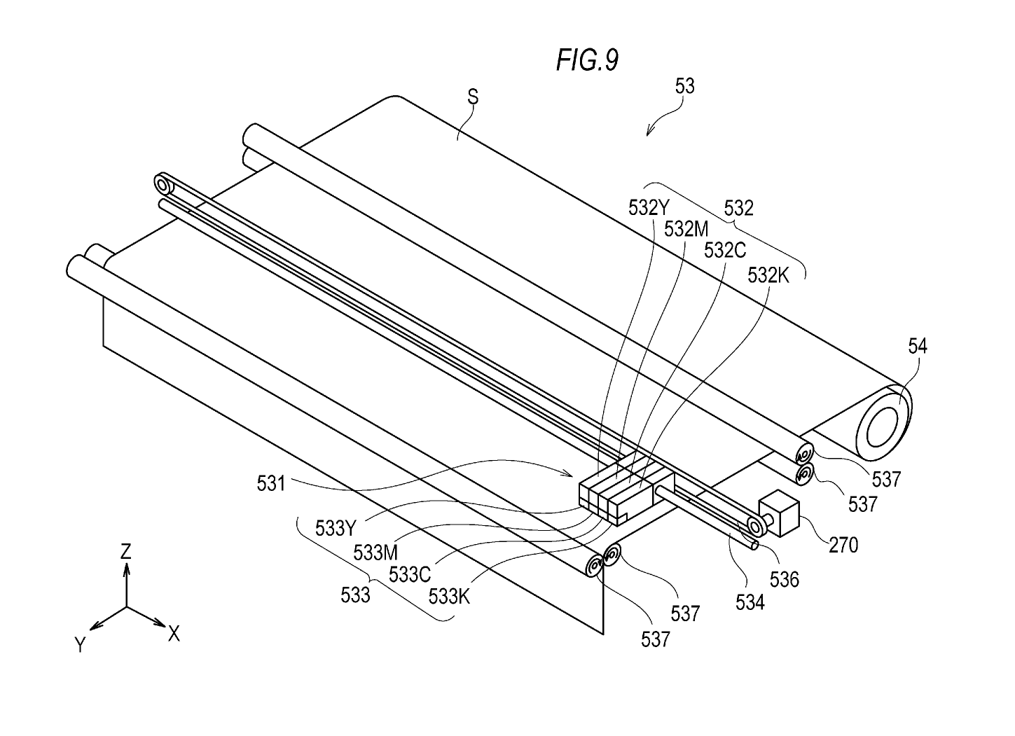

Next, a multi-function peripheral (MFP) 5 to which the image sensor unit 1 is applied is described with reference to FIGS. 8 and 9. FIG. 8 is an external perspective view schematically showing a configuration example of the multi-function peripheral 5. FIG. 9 is a perspective view showing a configuration example of an image forming portion 53 of the multi-function peripheral 5. The multi-function peripheral 5 is an example of the reading apparatus and the image forming apparatus, and is a multi-function peripheral of a sheet-feeding image scanner and an inkjet printer.

The multi-function peripheral 5 includes a casing 51, an image reading portion 52, and an image forming portion 53. The casing 51 is provided with a reading object supply port 511 for taking a sheet-shaped reading object D, and a reading object discharge port 512 for discharging the reading object D. The conveyance path A for the reading object D is provided in the inside of the casing 51. A recording sheet roll 54 where a recording sheet S, which is an example of a recording medium, is wound is housed in or attached to the casing 51. A recording sheet discharge port 513 for discharging a printed recording sheet S (recording medium) is provided for the casing 51.

The image sensor unit 1 according to the embodiment of the present invention is applied to the image reading portion 52. The image reading portion supports reading of a large-sized reading object D, such as of A0 size or A1 size. The image reading portion 52 includes: the reading object conveyor rollers 521 as movement means for moving the sheet-shaped reading object D; and the drive mechanism that drives the reading object conveyor rollers 521. The image reading portion 52 further includes a reading object collecting unit 522 provided on the rear surface of the casing 51. The reading object conveyor rollers 521 driven by the drive mechanism conveys the reading object D inserted through the reading object supply port 511, on the conveyance path A at a predetermined speed. Accordingly, the reading object D is relatively moved with respect to the image sensor unit 1 in the sub-scan direction. The image sensor unit 1 reads the conveyed reading object D (relatively moving in the sub-scan direction) according to the reading operation described above. The reading object conveyor rollers 521 further convey the read reading object D, and discharge the object through the reading object discharge port 512 to the outside of the casing 51. The reading object D discharged through the reading object discharge port 512 is put into the reading object collecting unit 522 provided on the rear surface of the casing 51.

In the embodiment of the present invention, the configuration where the reading object conveyor rollers 521 as the movement means, and the drive mechanism move the reading object D is described as the example. The configuration is no limited to such a configuration. The movement means is only required to have a configuration of moving at least one of the image sensor unit 1 and the reading object D, thereby relatively moving the image sensor unit 1 and the reading object D.

The image forming portion 53 forms (prints) an image on the recording sheet S, which is an example of the recording medium. The image forming portion 53 includes a printer head 531, a printer head sliding shaft 534, a printer head drive motor 535, a belt 536 attached to the printer head 531, and a recording sheet conveyer roller 537. The printer head 531 includes, for example, ink tanks 532 that include yellow (Y), magenta (M), cyan (C) and black (K) inks, and discharge heads 533 provided for the respective ink tanks 532.

In the image forming portion 53, the recording sheet S is conveyed by the recording sheet conveyer rollers 537 driven by the drive mechanism. The printer head 531 mechanically moves the belt 536 through a drive force by the printer head drive motor 535, thereby moving in a print direction (main-scan direction) along the printer head sliding shaft 534 while performing printing on the recording sheet S on the basis of the electric signal. The printed recording sheet S is cut. The cut recording sheet S is conveyed by the recording sheet conveyer rollers 537, and is discharged through the recording medium discharge port 513. The recording sheet S discharged through the recording medium discharge port 513 is put into the recording sheet collection unit 538 provided below the casing 51.

In the embodiment of the present invention, the example where the image forming portion 53 is of the inkjet type is described. The type of the image forming portion 53 is not specifically limited. The image forming portion 53 may be of any type among a photoelectric, thermal transfer, dot impact types.

Furthermore, in the embodiment of the present invention, the example where the image sensor unit 1 is applied to the multi-function peripheral (the reading apparatus, and the image forming apparatus) is described. However, the application target of the image sensor unit 1 is not limited to the reading apparatus, the image forming apparatus, and the multi-function peripheral thereof. For example, the image sensor unit 1 according to the embodiment of the present invention is applicable to a reticle tester (reticle test device) that tests a reticle used in a semiconductor manufacturing step.

In the embodiment described above, the image sensor unit is described as the sensor unit. The present invention is not limited to the image sensor unit that reads the image. For example, the unit is applicable to a sensor unit that detects a specific substance, that is, detects presence or absence of the specific substance on the basis of incident light. Such a sensor unit may be a unit for determining the authenticity, a unit for testing food or the like.

The sensor unit is only required to have a configuration that includes a module where multiple wiring boards mounted with sensor chips are connected to each other. As described in the embodiment described above, the module may have a configuration that is used in a manner detachably housed in another apparatus (serving as a part of the other apparatus), or the module may be a single, independent apparatus. For example, the configuration may be adopted where a scanner device that houses the module is arranged in a (commercial) printer that includes an image forming device of an inkjet type or an electrophotographic type, in order to test an image formed on a recording medium during conveyance of the recording medium.

The embodiment of the present invention has thus been described in detail with reference to the drawings. However, the present invention is not limited to the embodiment described above. Various modifications can be made in a range without departing from the spirit of the present invention. For example, the embodiment describes the example where the sensor portion includes two wiring boards. However, the number of wiring boards provided in the sensor portion is not specifically limited. The sensor chip provided on the wiring board in the sensor portion is not limited to photodiode array.

The present invention can prevent the sensors provided for the adjoining wiring boards from being broken by their mutual contact.

It should be noted that the above embodiments merely illustrate concrete examples of implementing the present invention, and the technical scope of the present invention is not to be construed in a restrictive manner by these embodiments. That is, the present invention may be implemented in various forms without departing from the technical spirit or main features thereof.

What is claimed is:

1. A sensor unit, comprising:
a line sensor that includes a plurality of light receiving portions arranged in an aligned manner; and
a plurality of elongated-shaped wiring boards provided with the line sensors,
wherein a plurality of the wiring boards are arranged such that end faces in a longitudinal direction face each other,
at least one of the line sensors protrudes from the end face in a top view of the wiring board, and
a resin material is provided between the end faces.

2. The sensor unit according to claim 1, wherein the resin material is provided at two or more sites between the end faces.

3. The sensor unit according to claim 1, wherein the resin material is provided so as to be in contact with each of the wiring boards.

4. The sensor unit according to claim 3, wherein the resin material is provided at positions where the material cannot be viewed to overlap with the sensors in the top view of the wiring boards.

5. The sensor unit according to claim 1, wherein the resin material is a photo-curable resin, or a cyanoacrylate resin.

6. The sensor unit according to claim 1, further comprising
a base member provided with a plurality of the wiring boards,
wherein the resin material arranged between the end faces is provided so as to be in contact also with the base member.

7. The sensor unit according to claim 6, wherein the base member and the wiring boards adhere to each other with an adhesive member other than the resin material.

8. The sensor unit according to claim 1,
wherein the line sensors include a plurality of light receiving portions arranged in the longitudinal direction, and
the light receiving portions provided at outermost ends in the line sensors provided at outermost ends of the wiring boards have an interval of between 50 and 300% of an interval between the adjoining light receiving portions in the line sensor.

9. A reading apparatus, comprising:
a sensor unit; and
movement means for moving at least one of the sensor unit and a reading object,
the reading apparatus moving at least one of the sensor unit and the reading object while causing the sensor unit to read the reading object,
wherein the sensor unit is the sensor unit according to claim 1.

10. An image forming apparatus, comprising:
an image forming portion that forms an image on a recording medium;
a sensor unit; and
movement means for moving at least one of the sensor unit and a reading object,
the image forming apparatus moving at least one of the sensor unit and the reading object while causing the sensor unit to read the reading object formed in the image forming portion,
wherein the sensor unit is the sensor unit according to claim 1.
